(19) United States
(12) Patent Application Publication
(10) Pub. No.: US 2025/0391684 A1
(43) Pub. Date: Dec. 25, 2025

(54) WAFER TRANSFER SYSTEM, AND METHOD FOR CONFIRMING POSITIONAL ACCURACY OF A WAFER TRANSFER ROBOT

(71) Applicant: Taiwan Semiconductor Manufacturing Company, Ltd., Hsinchu (TW)

(72) Inventors: Lung-Yin TANG, Hsinchu (TW); Shao-Wei HUANG, Hsinchu (TW); Hsin-Sheng LIANG, Hsinchu (TW)

(73) Assignee: Taiwan Semiconductor Manufacturing Company, Ltd., Hsinchu (TW)

(21) Appl. No.: 18/750,268

(22) Filed: Jun. 21, 2024

(51) Int. Cl. H01L 21/67; B65G 47/91; H01L 21/677; H01L 21/683; H01L 21/687

(52) U.S. Cl. CPC H01L 21/67259; B65G 47/91; H01L 21/67778; H01L 21/6838; H01L 21/68707

(57) ABSTRACT

A wafer transfer system includes a wafer holder, a reference wafer disposed in the wafer holder, and a vacuum wafer transfer robot. The reference wafer includes a wafer substrate, and a raised feature protruding from a backside surface of the wafer substrate. The vacuum wafer transfer robot includes a suction pad to pick up the reference wafer by exerting a suction force on the raised feature of the reference wafer. The suction pad corresponds to the raised feature in size.

### BACKGROUND

In semiconductor manufacturing, a semiconductor processing apparatus needs to transfer wafers from the outside of the apparatus to the inside for processing. Accordingly, accuracy in wafer transferring is an important factor to maintain normal and efficient manufacturing.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic top view of a wafer transfer system in accordance with some embodiments.

FIG. 2 is a schematic diagram illustrating a wafer transfer robot picking up a wafer from a wafer holder or delivering the wafer into the wafer holder in accordance with some embodiments.

FIGS. 3 and 4 are schematic diagrams illustrating the wafer transfer robot delivering a wafer into the wafer holder in accordance with some embodiments.

FIGS. 5 and 6 are schematic diagrams illustrating the wafer transfer robot having placed the wafer in a wafer slot of the wafer holder in accordance with some embodiments.

FIGS. 7 and 8 are schematic diagrams illustrating the wafer transfer robot exiting the wafer holder after the wafer has been placed in the wafer holder in accordance with some embodiments

FIGS. 9 and 10 are schematic diagrams illustrating different types of collisions between the wafer and the wafer holder that could potentially occur when a relative position between the wafer holder and a wafer handler of the wafer transfer robot deviates in accordance with some embodiments.

FIGS. 11 to 13 are schematic diagrams illustrating parameters that can be used to calibrate the wafer transfer robot in accordance with some embodiments.

FIG. 14 is a schematic diagram illustrating a height calibration of the wafer transfer robot in accordance with some embodiments.

FIGS. 15 and 16 are top views illustrating calibrations in angular positions and extension positions of the wafer transfer robot in accordance with some embodiments.

FIGS. 17 and 18 are respectively a top view and a sectional view illustrating a reference wafer in accordance with some embodiments.

FIGS. 19 and 20 are top views illustrating the wafer transfer robot picking up the reference wafer in accordance with some embodiments.

FIG. 21 is a schematic diagram illustrating that the reference wafer is placed in the wafer holder in accordance with some embodiments.

FIG. 22 is a schematic diagram illustrating the wafer transfer robot about to pick up the reference wafer in accordance with some embodiments.

FIG. 23 is a schematic diagram illustrating the wafer transfer robot picking up the reference wafer at an accurate position in accordance with some embodiments.

FIG. 24 is a schematic diagram illustrating the wafer transfer robot picking up the reference wafer at a deviated position in accordance with some embodiments.

FIGS. 25 to 27 are schematic diagrams illustrating a variant of the reference wafer and the wafer handler in accordance with some embodiments.

FIGS. 28 to 30 are schematic diagrams illustrating another variant of the reference wafer and the wafer handler in accordance with some embodiments.

FIG. 31 is a flow chart illustrating steps of a method for confirming positional accuracy of a vacuum wafer transfer robot in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects±10%, in some aspects±5%, in some aspects±2.5%, in some aspects±1%, in some aspects±0.5%, and in some aspects±0.1% from the specified amount, as such variations are appropriate to perform the disclosed methods or employ the disclosed compositions.

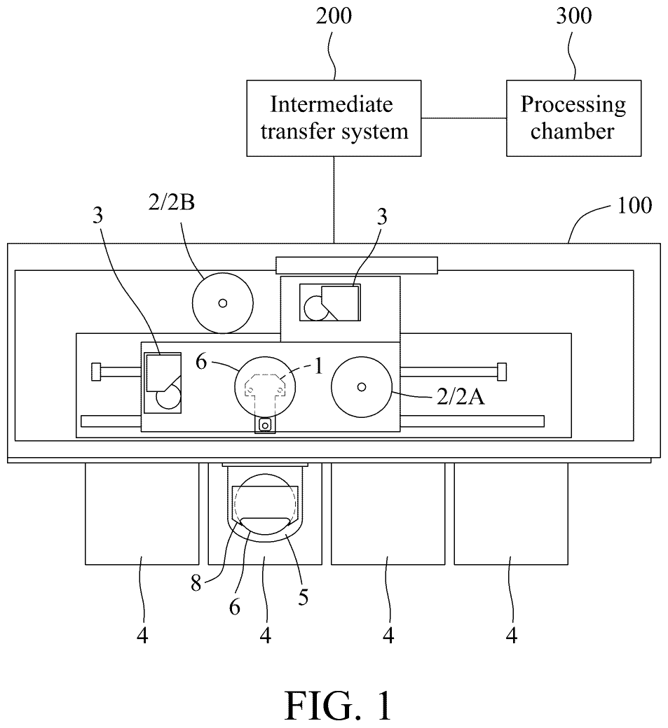

FIG. 1 illustrates a semiconductor processing apparatus in accordance with some embodiments. The semiconductor processing apparatus includes a plurality of load ports 4, a wafer transfer system 100 connected to the load ports 4, an intermediate transfer system 200 connected to the wafer transfer system 100, and a processing chamber 300 connected to the intermediate transfer system 200. The load ports 4 are configured to receive pods containing wafers and transferred from other processing tools. In the illustrative embodiment, a pod 5 is docked on one of the load ports 4, with a wafer cassette 8 that contains one or more wafers 6 (assuming that the wafer cassette 8 contains plural wafers 6 for the sake of illustration, but only one can be seen when viewed from top, as shown in FIG. 1) therein. The wafer transfer system 100 is configured to pick up the wafers 6 from the pod 5 for subsequent processing, and to, after completion of the processing, return the wafers 6 that have been processed back to the wafer cassette 8 in the pod 5. The intermediate transfer system 200 is configured to transfer wafers 6 that have been loaded into the wafer transfer system 100 to the processing chamber 300 for performing a process, such as a thin film deposition process, a photolithography process, an etching process, other semiconductor manufacturing processes, etc. After the process is finished for all of the wafers 6, the intermediate transfer system 200 transfers the wafers 6 back to the wafer transfer system 100.

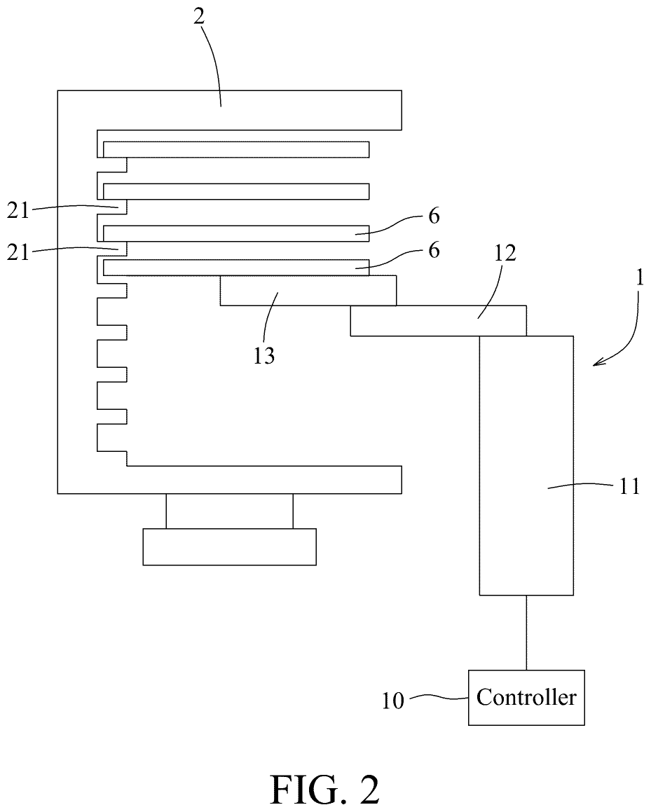

In the illustrative embodiment, the wafer transfer system 100 includes a wafer transfer robot 1, a plurality of wafer holders 2 and a plurality of wafer aligners 3. Further referring to FIG. 2, the wafer transfer robot 1 includes a controller 10, a drive mechanism 11 electrically connected to the controller 10, a robotic arm 12 connected to the drive mechanism 11 and electrically connected to the controller 10, and a wafer handler (also known as end effector) 13 electrically connected to the controller 10 and disposed on an end of the robotic arm 12. The drive mechanism 11 may include, for example, servo motors, linear actuators, pneumatic cylinders, other suitable components, or any combination thereof, depending on specific design requirements of the wafer transfer robot 1, and this disclosure is not limited in this respect. The robotic arm 12 is driven by the drive mechanism 11 to move in order to transfer the wafer 6 that has been picked up by the wafer handler 13 to a desired location (e.g., one of the pod 5, the wafer holders 2 and the wafer aligners 3 in FIG. 1). In the illustrative embodiment, the wafer transfer robot 1 is a vacuum-type robot, and the wafer hander 13 may include a vacuum chuck that uses suction to create a vacuum seal between the wafer handler 13 and the wafer 6, ensuring a stable grip without causing damage to a surface of the wafer 6. The controller 10 may receive commands from software, and coordinate operations of the drive mechanism 11, the robotic arm 12 and the wafer handler 13 accordingly to pick up, transfer, and place wafers with precision and accuracy. In accordance with some embodiments, the drive mechanism 11, the robotic arm 12, and/or the wafer handler 13 may include sensors and/or feedback mechanisms for the controller 10 to monitor, for example, the position, orientation, and status of the wafer 6, the vacuum level within the vacuum chuck when the vacuum chuck is gripping the wafer 6, other suitable parameters, or any combination thereof.

In the illustrative embodiment, the wafer holders 2 include a buffer cassette 2A, and a dummy cassette 2B that contains one or more dummy wafers (not shown) therein. When the wafers 6 are transferred to the semiconductor processing apparatus from the pod 5 for processing, the pod 5 would be docked on one of the load ports 4, and the wafer transfer robot 1 would pick up the wafers 6 from the wafer cassette 8 in the pod 5, and put the wafers 6 into the buffer cassette 2A, one after another. In detail, the wafer transfer robot 1 may pick up the wafers 6 in the pod 5 one at a time, and transfer the picked-up wafer 6 to one of the wafer aligners 3. The wafer aligner 3 adjusts orientation of the wafer 6 based on a notch or a flat of the wafer 6, and then the wafer transfer robot 1 picks up and transfers the wafer 6 from the wafer aligner 3 to the buffer cassette 2A. Because orientation adjustment takes time, while one of the wafers 6 undergoes orientation adjustment in one of the wafer aligners 3, the wafer transfer robot 1 may pick up and transfer another wafer 6 from the pod 5 to another wafer aligner 3 for orientation adjustment. Subsequently, the wafer transfer robot 1 retrieves the wafer 6 that has completed the orientation adjustment earlier from the corresponding wafer aligner 3 and places it into the buffer cassette 2A. The wafer transfer robot 1 then proceeds to transfer the wafer 6 that has then newly completed the orientation adjustment into the buffer cassette 2A, or take yet another wafer 6 from the pod 5 to a vacant wafer aligner 3 for orientation adjustment. In view of the orientation adjustment, the wafers 6 in the buffer cassette 2A would have the same orientation, which may be important or crucial for the upcoming process. The use of multiple wafer aligners 3 effectively reduces time required for transferring all of the wafers 6 from the pod 5 into the buffer cassette 2A.

In accordance with some embodiments, the semiconductor processing apparatus is configured to perform processing only when a full lot is present for processing. Namely, each of the wafer slots in the buffer cassette 2A must be filled with a wafer before proceeding to the next step. When all of the wafers 6 carried by the pod 5 have been transferred to the buffer cassette 2A but there is still one or more empty wafer slots present in the buffer cassette 2A, the wafer transfer robot 1 would take one or more dummy wafers from the dummy cassette 2B to fill the empty wafer slots in the buffer cassette 2A. Then, the intermediate transfer system 200 picks up the entire buffer cassette 2A, and transfer the wafers 6 in the buffer cassette 2A to the processing chamber 300 for processing. In accordance with some embodiments, the intermediate transfer system 200 may include a gripper arm (not shown) for securely holding and manipulating the entire buffer cassette 2A filled with wafers.

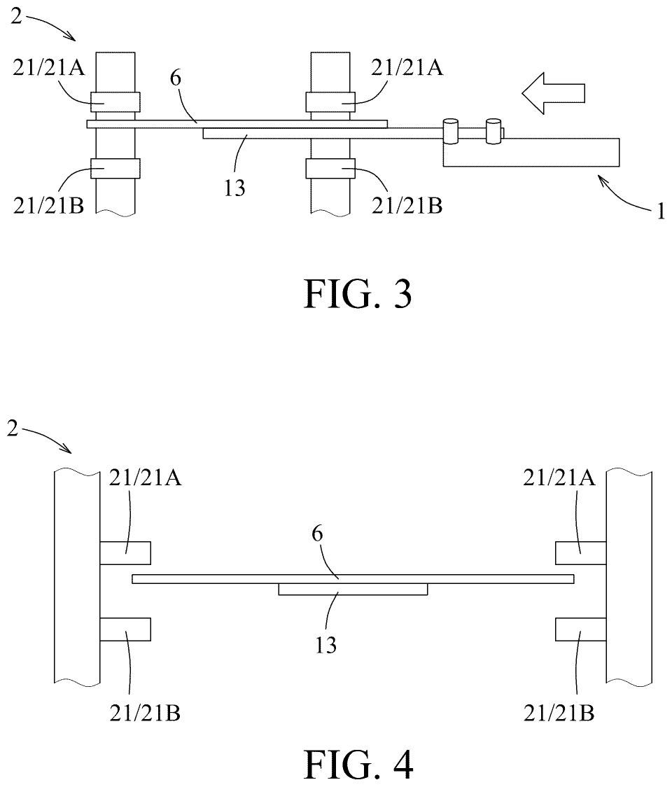

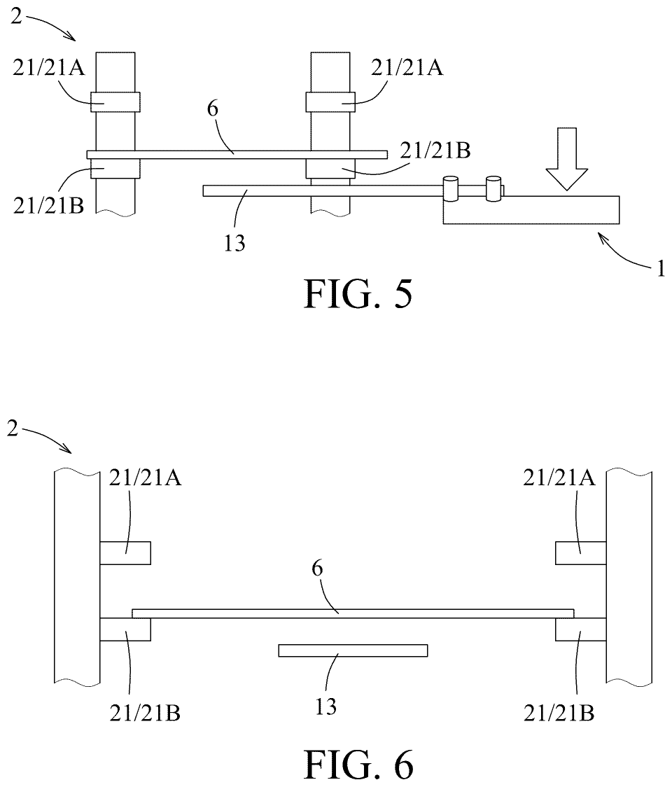

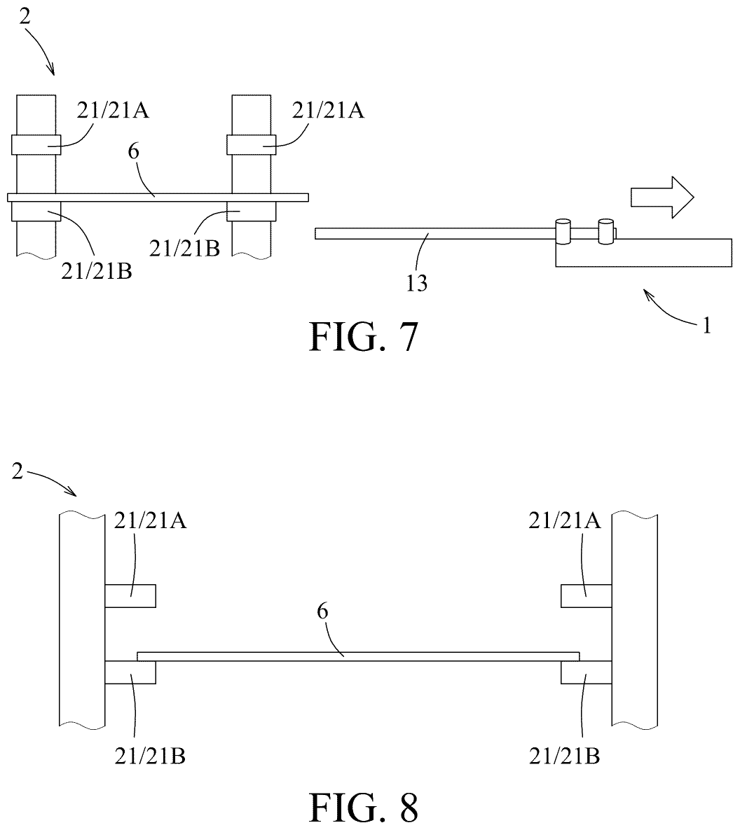

FIGS. 3 through 8 depict a procedure of the wafer transfer robot 1 placing the wafer 6 into a wafer slot of a wafer holder 2 (either the buffer cassette 2A or the dummy cassette 2B), shown from side views (see FIGS. 3, 5 and 7) and front views (see FIGS. 4, 6 and 8 that respectively correspond to FIGS. 3, 5 and 7). The wafer holder 2 is formed with a plurality of protrusions 21 that define the wafer slots in the wafer holder 2. In FIGS. 3 and 4, the wafer transfer robot 1 extends the wafer handler 13 that is holding the wafer 6 into the wafer holder 2, positioning the wafer 6 at a height between upper protrusions 21A and lower protrusions 21B. In FIGS. 5 and 6, the wafer transfer robot 1 moves the wafer handler 13 downward, landing the wafer 6 on the lower protrusions 21B. Then, the wafer handler 13 releases the suction of the wafer 6, allowing the wafer 6 to detach from the wafer handler 13. In FIGS. 7 and 8, the wafer transfer robot 1 pulls the wafer handler 13 out of the wafer holder 2, leaving the wafer 6 in the wafer slot defined by the upper protrusions 21A and the lower protrusions 21B. A process of removing the wafer 6 from the wafer slot of the wafer holder 2 is the reverse of placing the wafer 6 into the wafer slot, so details thereof are omitted herein for the sake of brevity.

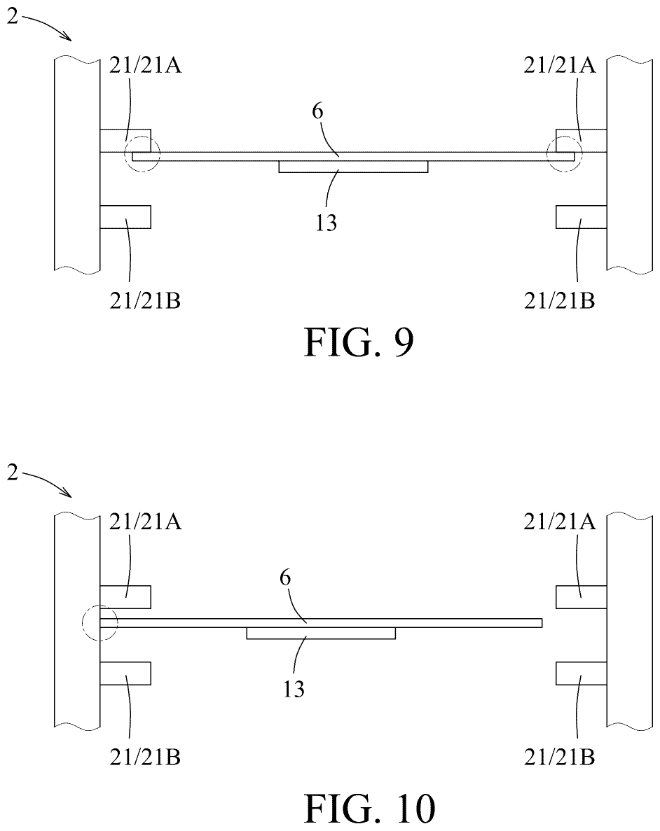

FIGS. 9 and 10 depict different types of positional deviations between the wafer handler 13 and the wafer holder 2. The positional deviation may stem from various factors. In one example, the position of the wafer handler 13 may gradually deviate over time due to prolonged use. In one example, the position of the wafer holder 2 may change after repair or maintenance of the semiconductor processing apparatus, which may involve replacement of the wafer holder 2. Other factors may cause the positional deviation between the wafer handler 13 and the wafer holder 2 as well, but this disclosure is not limited in this respect. FIG. 9 illustrates that an excessive height deviation between the wafer handler 13 and the wafer holder 2. If the wafer handler 13 holding the wafer 6 extends into the wafer holder 2 at this height position, the wafer 6 may hit the upper protrusions 21A, thereby causing damage such as scratches to the wafer 6. FIG. 10 illustrates that an excessive horizontal deviation between the wafer handler 13 and the wafer holder 2. If the wafer handler 13 holding the wafer 6 extends into the wafer holder 2 in this situation, the wafer 6 may hit a frame of the wafer holder 2, thereby causing residual stress or damage to the wafer 6.

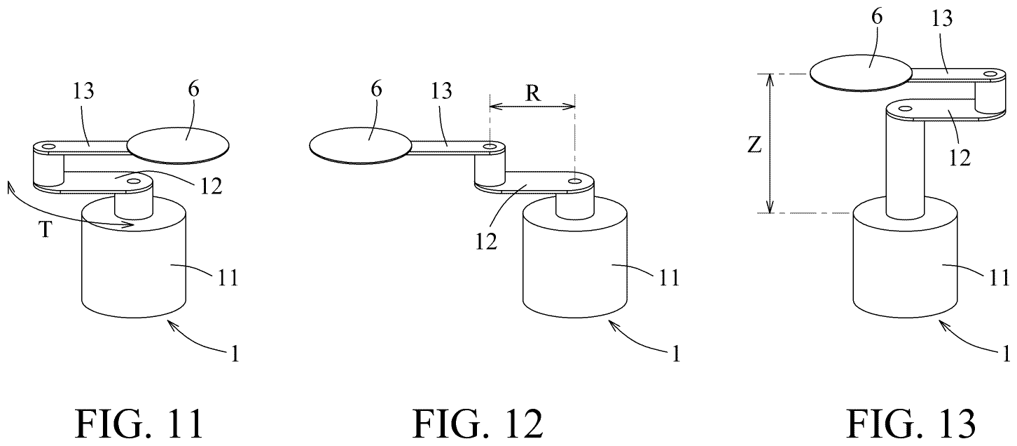

When the positional deviation between the wafer handler 13 and the wafer holder 2 is significant, a positional calibration procedure may be necessary before the wafer transfer robot 1 delivers the wafer 6 into the wafer holder 2 so as to optimize a relative position between the wafer handler 13 and the wafer holder 2, thereby preventing potential collision that may damage the wafer 6. FIGS. 11 to 13 depict calibrations of the wafer transfer robot 1 in three dimensions: twist (T), radius (R), and height (Z) in accordance with some embodiments. The dimension of “twist” is associated with an angular position of the robotic arm 12, which can be used to adjust a horizontal position of the wafer handler 13 relative to the protrusions 21 when the robotic arm 12 extends the wafer handler 13 into the wafer holder 2. The dimension of “radius” is associated with an extent of extension of the robotic arm 12, which can be used to adjust a depth the robotic arm 12 extends the wafer handler 13 into the wafer holder 2. The dimension of “height” is associated with a vertical distance the robotic arm 12 ascends, which can be used to adjust a height position of the wafer handler 13 when the robotic arm 12 extends the wafer handler 13 into a specific wafer slot of the wafer holder 2.

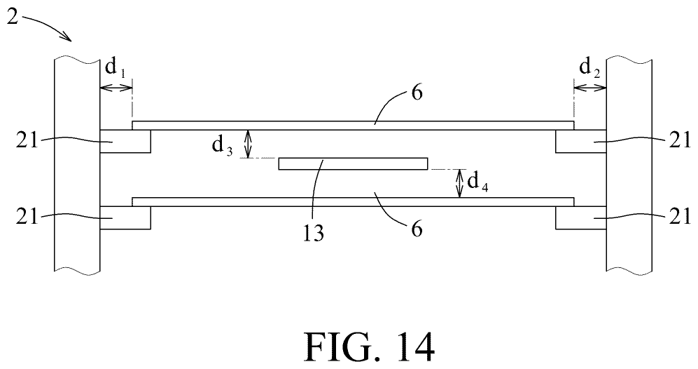

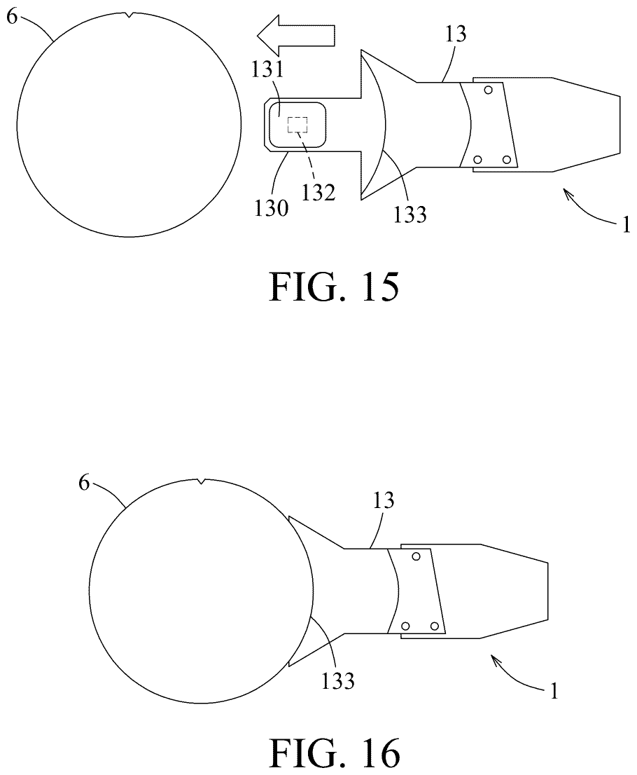

FIGS. 14 to 16 depict details of the positional calibration between the wafer transfer robot 1 and the wafer holder 2. In FIG. 14, two wafers 6 are placed in adjacent wafer slots of the wafer holder 2. Each of the wafers 6 is placed in such a way that a distance (d₁) between the wafer 6 and one sidewall of the wafer holder 2 is substantially the same as a distance (d₂) between the wafer 6 and an opposite sidewall of the wafer holder 2. Then, a height position of the robotic arm 12 (see FIG. 13) is adjusted in such a way that the wafer handler 13 is disposed between the wafers 6, with a distance (d₃) between the wafer handler 13 and the upper wafer 6 being substantially equal to a distance (d₄) between the wafer handler 13 and the lower wafer 6. That is to say, the wafer handler 13 is adjusted to be substantially equidistant from the upper and lower wafers 6 in a vertical direction. Then, the controller 10 (see FIG. 2) stores the adjusted height position of the robotic arm 12 into, for example, a non-volatile storage medium, such as flash memory, solid state drives, hard disk drives, etc. Because the distances among the wafer slots are uniform and known, after the height calibration is performed with respect to one of the wafer slots, the wafer transfer robot 1 can operate on all wafer slots at appropriate height positions without the need to calibrate the height position with respect to each wafer slot. FIG. 15 shows that the wafer handler 13 has a supporting plate 130, a suction pad 131 disposed on the supporting plate 130, and a vacuum sensor 132 disposed in the suction pad 131. The supporting plate 130 is configured to provide sufficient support for the wafer 6 when the wafer handler 13 is holding the wafer 6, and has an alignment arc 133 fitting a curvature of an edge of the wafer 6. The suction pad 131 is configured to pick up the wafer 6 from below by suction force. In accordance with some embodiments, the suction pad 131 is connected to a vacuum pump (not shown) that is, for example, integrated in the robotic arm 12 or the drive mechanism 11, but this disclosure is not limited in this respect. The suction pad 131 may include a hole (not shown) for the vacuum pump to induce vacuum between the suction pad 131 and the wafer 6, thereby creating the suction force to pick up the wafer 6. The vacuum sensor 132 is configured to sense a vacuum level in the suction pad 131 when the wafer handler 13 exerts the suction force on the wafer 6, and is electrically connected to the controller 10 (see FIG. 2) for sending the sensed vacuum level to the controller 10. The alignment arc 133 indicates an optimal position of the wafer 6 when the wafer handler 13 is holding the wafer 6, and thus can be used for positional calibration. During the positional calibration, the angular position and the extension of the robotic arm 12 are adjusted to align the alignment arc 133 of the wafer handler 13 with a part of the edge of the upper wafer 6, as shown in FIG. 16. Then, the controller 10 stores the adjusted angular position and the adjusted extension of the robotic arm 12 into the non-volatile storage medium. Following the abovementioned rules of calibration, the height position, the angular position, and the extension of the robotic arm 12 are optimized, thereby preventing occurrence of collision during the wafer transfer.

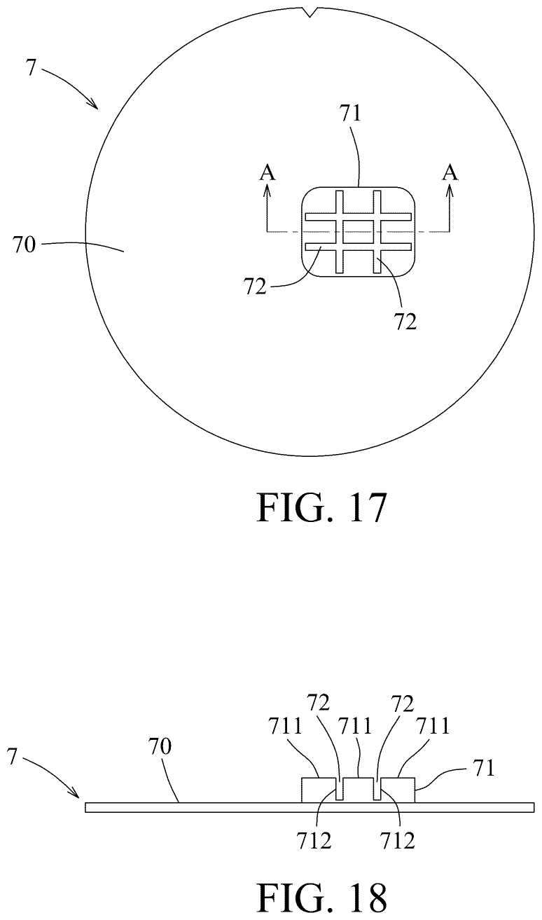

However, after prolonged use, the operation position of the robotic arm 12 may deviate from the calibrated position and deviations may accumulate over time. When the accumulated positional deviation reaches a significant level and is not found timely, collision between the wafer 6 and the wafer holder 2 may occur during the wafer transfer, resulting in reduced product yield. In order to prevent the potential risk of collision, a specifically-designed reference wafer is provided to promptly detect a significant positional deviation of the robotic arm 12 in accordance with some embodiments. FIG. 17 depicts a bottom view of a reference wafer 7 in accordance with some embodiments. The reference wafer 7 has a wafer substrate 70, which is an ordinary semiconductor wafer, and a raised feature (or a protuberance) 71 protruding from a backside surface of the wafer substrate 70. In accordance with some embodiments, the raised feature 71 may be formed using, for example, three-dimensional (3D) printing, and may be made of, for example, a plastic material, a ceramic material, other suitable materials, or any combination thereof. In the illustrative embodiment, the raised feature 71 has a top surface formed with one or more grooves 72, and the grooves 72 can be classified into a first group and a second group that intersect each other, but this disclosure is not limited in this respect. The depths of the grooves 72 may be either smaller than or equal to a height of the raised feature 71, which may range from about 0.1 mm to about 2 mm, but this disclosure is not limited in this respect. In accordance with some embodiments, the widths of the grooves 72 may range from about 0.1 mm to about 3 mm, but this disclosure is not limited in this respect. Referring to FIG. 18, the top surface of the raised feature 71 has a plurality of top portions 711 spaced apart from each other, and one or more recessed portions 712 interconnecting the top portions 711.

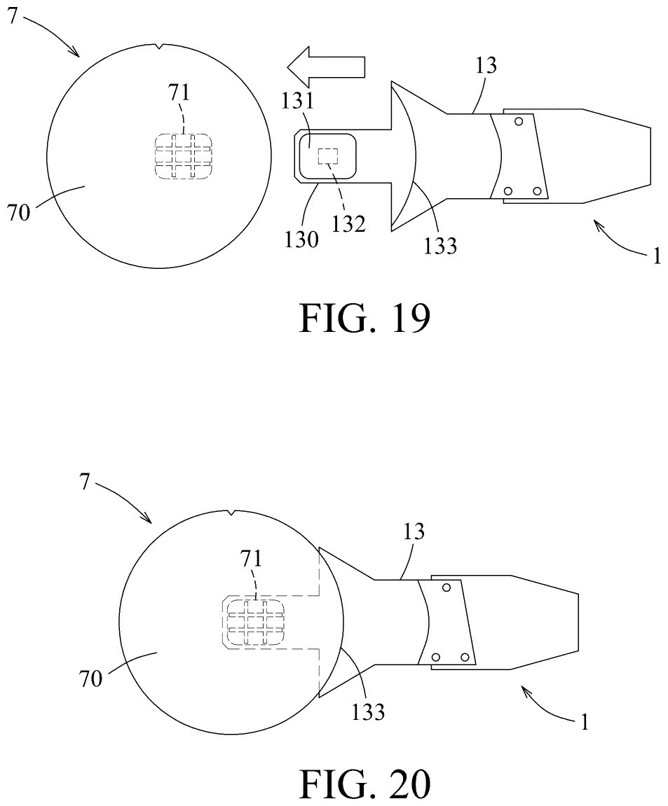

Further referring to FIGS. 19 and 20, the raised feature 71 is formed to have a size and a shape that correspond to a size and a shape of the suction pad 131, and that allow the raised feature 71 to completely cover the suction pad 131 when viewed from the top. In accordance with some embodiments, the raised feature 71 is made to have substantially the same size and substantially the same shape as the suction pad 131. In accordance with some embodiments, the raised feature 71 and the suction pad 131 may have shapes of the same type (e.g., both being polygons with the same number of sides, where each side of the raised feature 71 is parallel to a respective side of the suction pad 131 when the reference wafer 7 is arranged in a specific orientation, or both being circular, or both being elliptical, or one being circular and the other being elliptical), and the size of the raised feature 71 is made to be slightly greater than the size of the suction pad 131 to allow for some tolerance for positional deviation of the robotic arm 12. In one example where the shape of the suction pad 131 is a polygon, the shape of the raised feature 71 may be a polygon of the same type, with the same number of sides (i.e., each side of the raised feature 71 is parallel to a respective side of the suction pad 131 when the reference wafer 7 is arranged in a specific orientation), with each side of the raised feature 71 being greater than the respective side of the suction pad 131 by a tolerance length, which may range from about 0.1 mm to about 8 mm. In one example where the suction pad 131 is circular, the raised feature 71 may be circular as well, with a diameter of the raised feature 71 being greater than a diameter of the suction pad 131 by a tolerance length, which may range from about 0.1 mm to about 8 mm. In accordance with some embodiments, the shape of the raised feature 71 may be different from the shape of the suction pad 131, and the size of the raised feature 71 is made to be slightly greater than the size of the suction pad 131 to allow for some tolerance for positional deviation of the robotic arm 12. In one example where the shape of the suction pad 131 is a circle, the shape of the raised feature 71 may be a square or a rectangle, with each side of the raised feature 71 being greater than a diameter of the suction pad 131 by a tolerance length, which may range from about 0.1 mm to about 8 mm. The raised feature 71 is formed on the backside surface of the wafer substrate 70 at a location where, with the wafer substrate 70 being arranged in a specific orientation and a specific part of the edge of the wafer substrate 70 being aligned with the alignment arc 133, the suction pad 131 is completely covered by the raised feature 71 (i.e., a projection of the suction pad 131 onto the reference wafer 7 falling completely within the raised feature 71), so the suction pad 131 would completely grip onto the raised feature 71 (via the suction force) during the picking up of the reference wafer 7. In accordance with some embodiments, a distance between a center of the raised feature 71 and a center of the specific part of the edge of the wafer substrate 70 is substantially equal to a distance between a center of the suction pad 131 and a center of the alignment arc 133.

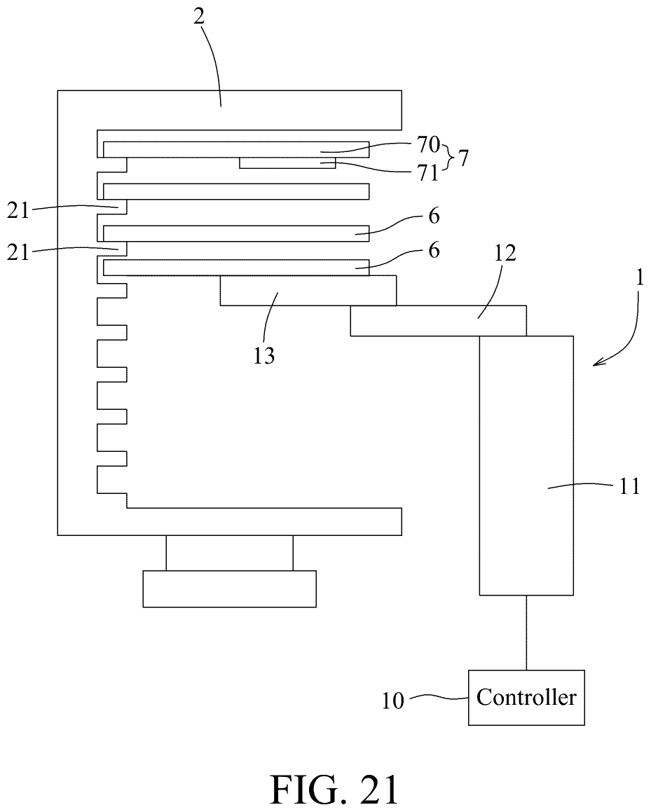

Referring to FIG. 21, the reference wafer 7 is placed in a wafer slot of the wafer holder 2, with the backside surface of the wafer substrate 70 facing downward. In accordance with some embodiments, the wafer holder 2, which may be either the buffer cassette 2A or the dummy cassette 2B in FIG. 1, is made to have more wafer slots than the wafer cassette 8 carried by the pod 5, allowing the wafer holder 2 to accommodate the reference wafer 7 and all the wafers 6 from the wafer cassette 8 of a full lot at once. In the illustrative embodiment, the reference wafer 7 is placed in the upmost wafer slot of the wafer holder 2, but this disclosure is not limited in this respect.

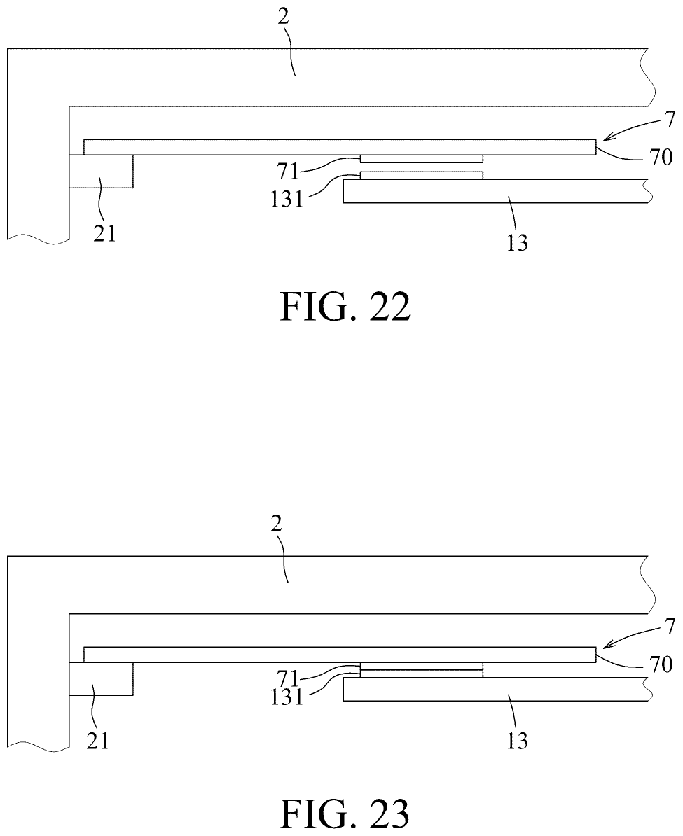

FIGS. 22 to 24 illustrate how the reference wafer 7 is used to confirm positional accuracy of the wafer handler 13. In FIG. 22, based on a stored position setting, the wafer handler 13 extends into the wafer holder 2 at a height position below the reference wafer 7. At this moment, the suction force has not been generated in the suction pad 131. Then, the wafer handler 13 is elevated to make the suction pad 131 contact the reference wafer 7. In FIG. 23, the suction pad 131 is successfully aligned with and lands on the raised feature 71. Further referring to FIG. 17, in the raised feature 71, each of the grooves 72 has two opposite ends, and each of the ends is spaced apart from all of the edges of the raised feature 71. The grooves 72 define a suction area that is smaller than the suction pad 131. For example, assuming that those of the grooves 72 extending horizontally in FIG. 17 have a length of L₁, and those of the grooves 72 extending vertically in FIG. 17 have a length of L₂, the grooves 72 cooperatively define a rectangular suction area of (L₁×L₂), where L₁ is smaller than a length of the suction pad 131 in the horizontal direction of FIGS. 17, and L₂ is smaller than a width of the suction pad 131 in the vertical direction of FIG. 17. In accordance with some embodiments, the suction area is configured in such a way that, as long as the suction pad 131 completely lands on the raised feature 71, the suction pad 131 would completely cover the suction area (i.e., completely cover the grooves 72). In accordance with some embodiments, the suction area is configured in such a way that the suction pad 131 is unable to completely cover the grooves 72 (i.e., a part of the grooves 72 would be exposed) when the suction pad 131 does not completely land on the raised feature 71 (i.e., the suction pad 131 partly lands on the raised feature 71 and partly lands on the backside surface of the wafer substrate 70).

Referring back to FIG. 23, after the suction pad 131 contacts the raised feature 71, the vacuum pump that is connected to the suction pad 131 is activated to generate the suction force in the suction pad 131, causing the suction pad 131 to completely grip onto the raised feature 71 via the suction force to pick up the reference wafer 7. At this moment, the vacuum sensor 132 (see FIG. 19) is triggered to sense the vacuum level in the suction pad 131 (more precisely, between the suction pad 131 and the reference wafer 7), and transmits the sensed vacuum level to the controller 10 of the wafer transfer robot 1 (see FIG. 21). Because the suction pad 131 completely covers the grooves 72 and thus isolates the grooves 72 from the external environment, external air is unable to enter the suction pad 131, and the sensed vacuum level would be at a normal value greater than or equal to a predetermined threshold. In response to the sensed vacuum level being normal (i.e., greater than or equal to the predetermined threshold), the wafer transfer robot 1 may descend the wafer handler 13 and then deactivate the vacuum pump to place the reference wafer 7 back in the wafer slot, and continue with the next action (e.g., transferring another wafer 6) or wait for an instruction. Since the reference wafer 7 is used only for confirming whether the wafer handler 13 is at an accurate position, especially in terms of the angular position and the depth of extension, it is unnecessary for the wafer handler 13 to take the reference wafer 7 out of the wafer holder 2, and the wafer handler 13 may simply grip onto the reference wafer 7, check the vacuum level, and then put down the reference wafer 7 after the checking of the vacuum level.

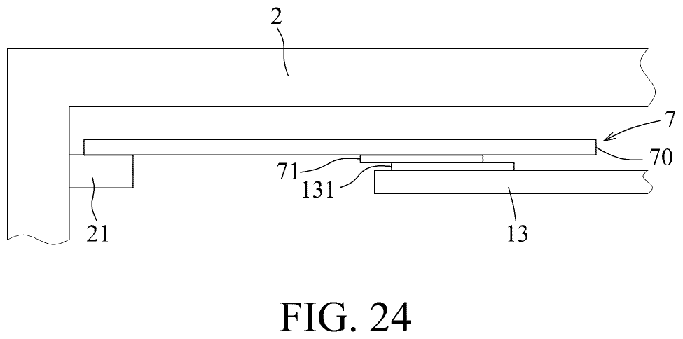

FIG. 24 illustrates a situation where the wafer handler 13 deviates from the raised feature 71 in position during the picking up of the reference wafer 7. When the suction pad 131 does not completely cover the suction area, a part of the grooves 72 (see FIG. 17) would be exposed, and external air would thus enter the suction pad 131 through the exposed part of the grooves 72, making the vacuum pump unable to effectively create vacuum in the suction pad 131. When the vacuum level sensed by the vacuum sensor 132 is lower than the predetermined threshold, the controller 10 (see FIG. 21) may control the robotic arm 12 (see FIG. 21) to descend the wafer handler 13 to place the reference wafer 7 back in the wafer slot, and generate and output a notification to notify relevant personnel of a noticeable positional deviation of the wafer handler 13. The notification may be presented through use of, for example, a display, a light emitting diode (LED) device, a buzzer, a speaker, other suitable devices, or any combination thereof. Upon receipt of the notification, the relevant personnel may execute the aforesaid positional calibration procedure, so as to prevent further deviation of the wafer handler 13.

Referring to FIGS. 17 through 20 again, in order to facilitate the wafer handler 13 to firmly grip onto the raised feature 71 by the suction force, the raised feature 71 is made as a platform in accordance with some embodiments, where the top portions 711 are smooth and flat. In accordance with some embodiments, the top portions 711 are parallel to the backside surface of the wafer substrate 70. In accordance with some embodiments, the top portions 711 are coplanar. In accordance with some embodiments, the top surface of the raised feature 71 is not formed with any grooves therein, and may be simply a flat surface parallel to the backside surface of the wafer substrate 70. Given the height difference between the raised feature 71 and the backside surface of the wafer substrate 70, even if the top surface of the raised feature 71 is completely flat with no grooves, there would still be a gap between the suction pad 131 and the reference wafer 7 when the suction pad 131 does not completely cover and grip onto the raised feature 71 (i.e., a part of the suction pad 131 lands on the raised feature 71, whereas another part of the suction pad 131 lands on the wafer substrate 70). As a result, the external air may enter the suction pad 131 through the gap when the vacuum pump is activated, thereby reducing the vacuum level in the suction pad 131. However, existence of the grooves 72 may induce a more prominent reduction of the vacuum level when the suction pad 131 does not completely land onto the raised feature 71.

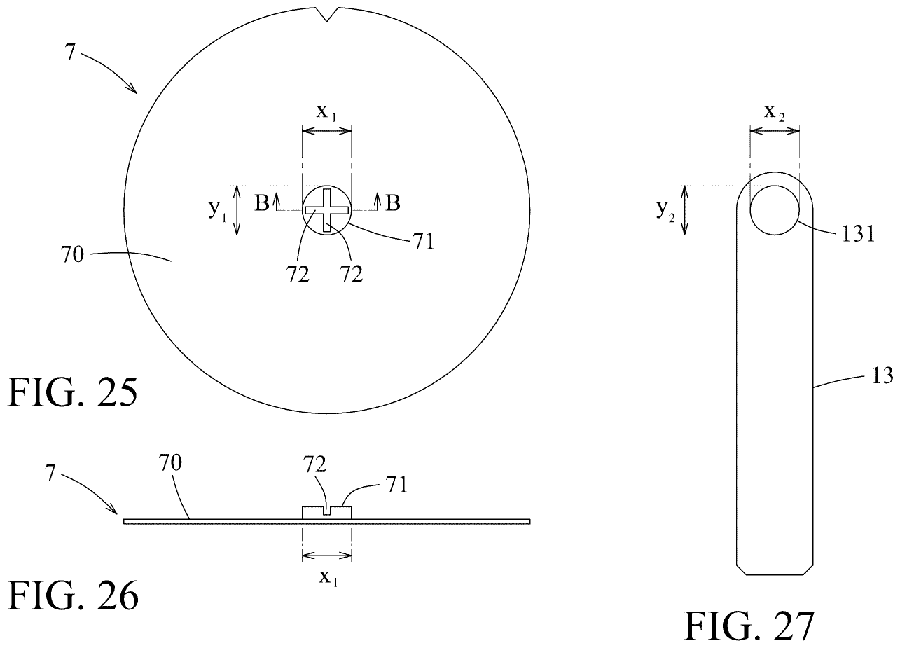

Since the shape of the suction pad 131 may vary, the raised feature 71 may have different designs in order to match the suction pad 131 in shape. FIGS. 25 through 27 illustrate a variant of the combination of the raised feature 71 and the suction pad 131. In this variant, the wafer handler 13 is I-shaped, and is equipped with a circular or elliptical suction pad 131, and the raised feature 71 is correspondingly circular or elliptical. Parameters x₁ and y₂ respectively represent a width and a length of the raised feature 71, and parameters x₂ and y₂ respectively represent a width and a length of the suction pad 131 and respectively correspond to the parameters x₁ and y₁. In a case where the raised feature 71 is circular, x₁=y₁, representing a diameter of the raised feature 71. In a case where the raised feature 71 is elliptical, x₁ and y₁ represent lengths of a major axis and a minor axis of the raised feature 71, respectively. In a case where the suction pad 131 is circular, x₂=y₂, representing a diameter of the suction pad 131. In a case where the suction pad 131 is elliptical, x₁ and y₁ represent lengths of a major axis and a minor axis of the suction pad 131, respectively. In accordance with some embodiments, x₁ is greater than or equal to x₂, and y₁ is greater than or equal to y₂, thereby enabling the suction pad 131 to completely cover and grip onto the raised feature 71. In this variant, the top surface of the raised feature 71 is formed with two grooves 72 that intersect at a center of the raised feature 71 to form a cross pattern, but this disclosure is not limited in this respect.

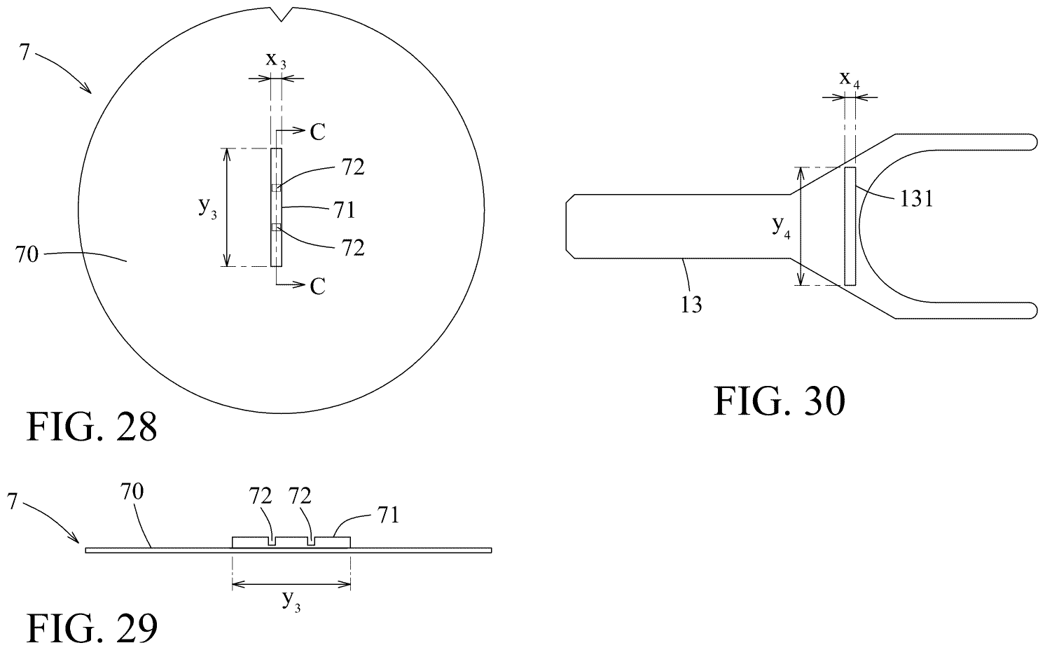

FIGS. 28 through 30 illustrate another variant of the set of the raised feature 71 and the suction pad 131. In this variant, the wafer handler 13 is Y-shaped, and is equipped with a strip-shaped suction pad 131, and the raised feature 71 is correspondingly strip-shaped. The raised feature 71 has a width of x₃ and a length of y₃, and the suction pad 131 has a width of x₄ and a length of y₄ that respectively correspond to the width x₃ and the length y₃ of the raised feature 71. In accordance with some embodiments, the width x₃ of the raised feature 71 is greater than or equal to the width x₄ of the suction pad 131, and the length y₃ of the raised feature 71 is greater than or equal to the length y₄ of the suction pad 131, thereby enabling the suction pad 131 to completely cover and grip onto the raised feature 71. In this variant, the top surface of the raised feature 71 is formed with two grooves 72 that extend in a widthwise direction of the raised feature 71, but this disclosure is not limited in this respect.

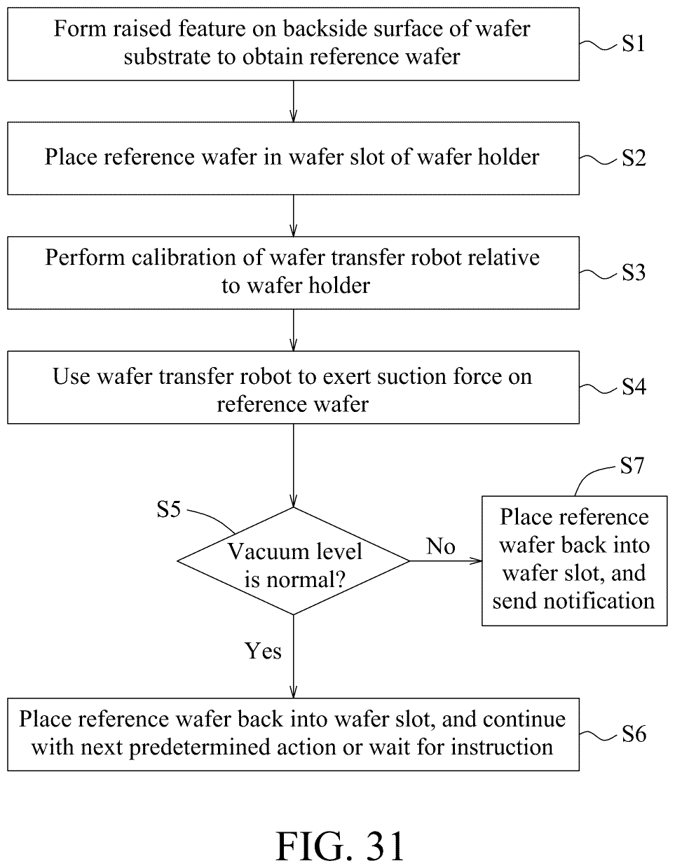

FIG. 31 illustrates a method for the wafer transfer system 100 to confirm positional accuracy of the wafer transfer robot 1. Further referring to FIG. 17, in step S1, a wafer is used to form the reference wafer 7. In accordance with some embodiments, 3D printing may be used to form the raised feature 71 on a backside surface of the wafer that serves as the wafer substrate 70. In accordance with some embodiments, the wafer used in step S1 may be a plain wafer that is absent of any pattern of circuits or devices on either the frontside surface or the backside surface thereof, but this disclosure is not limited in this respect. Referring to FIGS. 21 and 31, in step S2, the reference wafer 7 is placed into a wafer slot of the wafer holder 2, with the raised feature 71 facing downward. In step S3, a positional calibration of the wafer transfer robot 1 is performed relative to the wafer holder 2. The positional calibration may be performed using the aforesaid positional calibration procedure, which was introduced with reference to FIGS. 11 to 16, but this disclosure is not limited in this respect, and other suitable calibration methods may be used as well. Referring to FIGS. 19, 20 and 31, in step S4, the wafer handler 13 exerts the suction force on the reference wafer 7 through the suction pad 131, and the vacuum sensor 132 senses the vacuum level in the suction pad 131 in order to confirm the position of the wafer handler 13. As mentioned above, the raised feature 71 is configured in such a way that, when the suction pad 131 completely covers and grips onto the raised feature 71, the suction pad 131 would completely cover the suction area so the vacuum pump can effectively create vacuum in the suction pad 131. On the other hand, if the suction pad 131 fails to completely cover and grip onto the raised feature 71, the grooves 72 would be partly exposed and/or a gap would be formed between the suction pad 131 and the reference wafer 7, so the vacuum pump cannot effectively create vacuum in the suction pad 131. In step S5, the controller 10 (see FIG. 21) determines whether the vacuum level sensed by the vacuum sensor 132 is normal by comparing it with the predetermined threshold. The flow goes to step S6 in response to the sensed vacuum level being greater than or equal to the predetermined threshold, and goes to step S7 when otherwise. In step S6, the wafer transfer robot 1 places the reference wafer 7 back into the wafer slot, and continues with the next action according to an instruction received by the controller 10, or awaits an instruction that indicates the next action. In step S7, the wafer transfer robot 1 places the reference wafer 7 back into the wafer slot, and sends the notification for notifying relevant personnel of a noticeable positional deviation of the wafer handler 13, so they can recalibrate the wafer transfer robot 1. In accordance with some embodiments, steps S4 through S7 may be performed once for each lot of the wafers 6, either before transferring the lot of the wafers 6 from an external transport (e.g., the pod 5) to the wafer holder 2, after transferring the lot of the wafers 6 from the external transport to the wafer holder 2, before sending the lot of the wafers 6 out from the wafer holder 2, or after sending the lot of the wafers 6 out from the wafer holder 2, and this disclosure is not limited in this respect. In accordance with some embodiments, the abovementioned method as exemplified in FIG. 31 can be applied to the wafer aligners 3 (see FIG. 1) as well, as long as a wafer holder with at least one wafer slot is added to each of the wafer aligners 3 for accommodating the reference wafer 7.

In accordance with some embodiments, a wafer transfer system is provided to include a wafer holder, a reference wafer disposed in the wafer holder, and a vacuum wafer transfer robot. The reference wafer includes a wafer substrate, and a raised feature protruding from a backside surface of the wafer substrate. The vacuum wafer transfer robot includes a wafer handler, and the wafer handler includes a suction pad to pick up the reference wafer by exerting a suction force on the raised feature of the reference wafer. The suction pad corresponds to the raised feature in size.

In accordance with some embodiments, the vacuum wafer transfer robot has a wafer handler that includes a suction pad to pick up the reference wafer, and the raised feature is configured to allow the suction pad to be completely covered by the raised feature.

In accordance with some embodiments, the raised feature has a shape that is of a same type as a shape of the suction pad.

In accordance with some embodiments, the vacuum wafer transfer robot is configured to output a notification related to positional deviation of the wafer handler when the suction pad does not completely grip onto the raised feature via the suction force during the picking up of the reference wafer.

In accordance with some embodiments, the wafer handler includes a vacuum sensor disposed to sense a vacuum level in the suction pad, and the vacuum wafer transfer robot is configured to output a notification related to positional deviation of the wafer handler when the vacuum level sensed by the vacuum sensor during the picking up of the reference sensor is smaller than a predetermined threshold.

In accordance with some embodiments, the wafer handler has an alignment arc that fits a curvature of an edge of the wafer substrate of the reference wafer, and the raised feature is disposed on the backside surface of the wafer substrate at a location where, with a part of the edge of the wafer substrate being aligned with the alignment arc during the picking up of the reference wafer, the suction pad completely grips onto the raised feature via the suction force.

In accordance with some embodiments, the raised feature includes one of a plastic material and a ceramic material.

In accordance with some embodiments, the raised feature has a surface facing downward and having a first groove.

In accordance with some embodiments, the surface of the raised feature has a second groove transverse to the first groove.

In accordance with some embodiments, a method is provided for confirming positional accuracy of a vacuum wafer transfer robot. In one step, a reference wafer is placed in a wafer holder. The reference wafer includes a wafer substrate and a raised feature, the wafer substrate has a backside surface facing downward, and the raised feature protrudes from the backside surface of the wafer substrate. In one step, a wafer handler of the vacuum wafer transfer robot, exerts a suction force on the raised feature of the reference wafer to pick up the reference wafer. In one step, the vacuum wafer transfer robot outputs a notification that is related to a positional deviation of the wafer handler in response to a suction pad of the wafer handler not completely gripping onto a predefined area of the raised feature via the suction force during the picking up of the reference wafer.

In accordance with some embodiments, the raised feature has a shape that is of a same type as a shape of the suction pad.

In accordance with some embodiments, in one step, a vacuum sensor of the wafer handler senses a vacuum level in the suction pad during the picking up of the reference wafer. In one step, a controller of the wafer robot determines that the suction pad of the wafer handler does not completely grip onto the predefined area of the raised feature via the suction force in response to the vacuum level sensed by the vacuum sensor during the picking up of the reference wafer being smaller than a predetermined threshold.

In accordance with some embodiments, the raised feature includes one of a plastic material and a ceramic material.

In accordance with some embodiments, the raised feature has a surface facing downward when the reference wafer is placed in the wafer holder, and the surface of the raised feature is formed with a first groove.

In accordance with some embodiments, the surface of the raised feature has a second groove transverse to the first groove.

In accordance with some embodiments, the wafer handler has an alignment arc that fits a curvature of an edge of the reference wafer, and the raised feature is disposed on the backside surface of the wafer substrate at a location where, with a part of the edge of the reference wafer being aligned with the alignment arc during the picking up of the reference wafer, the suction pad completely grips onto the predefined area of the raised feature via the suction force.

In accordance with some embodiments, in one step, the vacuum wafer transfer robot is calibrated to align the part of the edge of the reference wafer with the alignment arc of the wafer handler during the picking up of the reference wafer.

In accordance with some embodiments, in one step, the raised feature is formed on the backside surface of the wafer substrate using three-dimensional printing.

In accordance with some embodiments, a wafer transfer system of a semiconductor processing apparatus is provided to include a buffer cassette disposed in the semiconductor processing apparatus, a reference wafer disposed in the buffer cassette, and a vacuum wafer transfer robot. The reference wafer includes a wafer substrate and a raised feature, the wafer substrate has a backside surface facing downward, and the raised feature protrudes from the backside surface of the wafer substrate. The vacuum wafer transfer robot is configured to transfer to-be-processed wafers between the buffer cassette and a wafer cassette in a pod, and to pick up the reference wafer by exerting a suction force on the raised feature of the reference wafer.

In accordance with some embodiments, the buffer cassette has more wafer slots than the wafer cassette in the pod, and one of the wafer slots of the buffer cassette accommodates the reference wafer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A wafer transfer system, comprising:
a wafer holder;
a reference wafer disposed in the wafer holder, and comprising a wafer substrate, and a raised feature protruding from a backside surface of the wafer substrate; and
a vacuum wafer transfer robot comprising a wafer handler, and the wafer handler comprising a suction pad to pick up the reference wafer by exerting a suction force on the raised feature of the reference wafer, wherein the suction pad corresponds to the raised feature in size.

2. The wafer transfer system according to claim 1, wherein the raised feature is configured to allow the suction pad to be covered by the raised feature.

3. The wafer transfer system according to claim 2, wherein the raised feature has a shape that is of a same type as a shape of the suction pad.

4. The wafer transfer system according to claim 2, wherein the vacuum wafer transfer robot is configured to output a notification related to positional deviation of the wafer handler when the suction pad does not completely grip onto the raised feature via the suction force during the picking up of the reference wafer.

5. The wafer transfer system according to claim 2, wherein the wafer handler comprises a vacuum sensor disposed to sense a vacuum level in the suction pad, and the vacuum wafer transfer robot is configured to output a notification related to positional deviation of the wafer handler when the vacuum level sensed by the vacuum sensor during the picking up of the reference sensor is smaller than a predetermined threshold.

6. The wafer transfer system according to claim 2, wherein the wafer handler has an alignment arc that fits a curvature of an edge of the wafer substrate of the reference wafer, and the raised feature is disposed on the backside surface of the wafer substrate at a location where, with a part of the edge of the wafer substrate being aligned with the alignment arc during the picking up of the reference wafer, the suction pad completely grips onto the raised feature via the suction force.

7. The wafer transfer system according to claim 1, wherein the raised feature comprises one of a plastic material and a ceramic material.

8. The wafer transfer system according to claim 1, wherein the raised feature has a surface facing downward and having a first groove.

9. The wafer transfer system according to claim 8, wherein the surface of the raised feature has a second groove transverse to the first groove.

10. A method for confirming positional accuracy of a vacuum wafer transfer robot, comprising:
placing a reference wafer in a wafer holder, wherein the reference wafer comprises a wafer substrate and a raised feature, the wafer substrate has a backside surface facing downward, and the raised feature protrudes from the backside surface of the wafer substrate;
by a wafer handler of the vacuum wafer transfer robot, exerting a suction force on the raised feature of the reference wafer to pick up the reference wafer; and
by the vacuum wafer transfer robot, outputting a notification that is related to a positional deviation of the wafer handler in response to a suction pad of the wafer handler not completely gripping onto a predefined area of the raised feature via the suction force during the picking up of the reference wafer.

11. The method according to claim 10, wherein the raised feature has a shape that is of a same type as a shape of the suction pad.

12. The method according to claim 10, further comprising:
by a vacuum sensor of the wafer handler, sensing a vacuum level in the suction pad during the picking up of the reference wafer; and
by a controller of the wafer robot, determining that the suction pad of the wafer handler does not completely grip onto the predefined area of the raised feature via the suction force in response to the vacuum level sensed by the vacuum sensor during the picking up of the reference wafer being smaller than a predetermined threshold.

13. The method according to claim 10, wherein the raised feature comprises one of a plastic material and a ceramic material.

14. The method according to claim 10, wherein the raised feature has a surface facing downward when the reference wafer is placed in the wafer holder, and the surface of the raised feature is formed with a first groove.

15. The method according to claim 14, wherein the surface of the raised feature has a second groove transverse to the first groove.

16. The method according to claim 10, wherein the wafer handler has an alignment arc that fits a curvature of an edge of the reference wafer, and the raised feature is disposed on the backside surface of the wafer substrate at a location where, with a part of the edge of the reference wafer being aligned with the alignment arc during the picking up of the reference wafer, the suction pad completely grips onto the predefined area of the raised feature via the suction force.

17. The method according to claim 16, further comprising: calibrating the vacuum wafer transfer robot to align the part of the edge of the reference wafer with the alignment arc of the wafer handler during the picking up of the reference wafer.

18. The method according to claim 10, further comprising: forming the raised feature on the backside surface of the wafer substrate using three-dimensional printing.

19. A wafer transfer system of a semiconductor processing apparatus, comprising:
a buffer cassette disposed in the semiconductor processing apparatus;
a reference wafer disposed in the buffer cassette, wherein the reference wafer comprises a wafer substrate and a raised feature, the wafer substrate has a backside surface facing downward, and the raised feature protrudes from the backside surface of the wafer substrate; and
a vacuum wafer transfer robot configured to transfer to-be-processed wafers between the buffer cassette and a wafer cassette in a pod, and to pick up the reference wafer by exerting a suction force on the raised feature of the reference wafer.

20. The wafer transfer system according to claim 19, wherein the buffer cassette has more wafer slots than the wafer cassette in the pod, and one of the wafer slots of the buffer cassette accommodates the reference wafer.
